(19) United States
(12) Patent Application Publication
(10) Pub. No.: US 2012/0318344 A1
(43) Pub. Date: Dec. 20, 2012

(54) PHOTOVOLTAIC MODULE WITH CHLOROSULFONATED POLYOLEFIN LAYER

(75) Inventors: CHEN QIAN ZHAO, Newark, DE (US); Jonathan Aaron Karas, Solon, OH (US); Simone M.P. Arizzi, Geneva (CH)

(73) Assignee: E. I. DU PONT DE NEMOURS AND COMPANY, Wilmington, DE (US)

(21) Appl. No.: 13/329,359

(22) Filed: Dec. 19, 2011

Related U.S. Application Data
(60) Provisional application No. 61/427,914, filed on Dec. 29, 2010.

(51) Int. Cl. H01L 31/0216

(52) U.S. Cl. 136/256

(57) ABSTRACT

A photovoltaic module comprises an active solar cell layer having a front light receiving side and opposite rear side, an encapsulant layer adhered to the rear side of the active solar cell layer, and a back-sheet adhered to the encapsulant layer. The back-sheet comprises a first polymer film adhered to said encapsulant layer, where the first polymer film comprises 20 to 95 weight percent chlorosulfonated polyolefin, such as chlorosulfonated polyethylene, based on the weight of the first polymer film, and 1 to 35 weight percent of adhesive based on the weight of the first polymer film. The first polymer film may further comprise 10 to 70 weight percent of inorganic particulates such as calcium carbonate, titanium dioxide, kaolin and clays.

### BACKGROUND OF THE INVENTION

1. Field of the Disclosure

The present invention relates to durable protective films and sheets for photovoltaic modules, and more particularly to the use in photovoltaic modules of chlorosulfonated polyolefin films or sheets such as chlorosulfonated polyethylene containing polymer films. The invention also relates to photovoltaic modules with durable chlorosulfonated polyethylene containing back-sheets.

2. Description of the Related Art

A photovoltaic module (also know as a solar cell module) refers to a photovoltaic device for generating electricity directly from light, particularly, from sunlight. Typically, an array of individual solar cells is electrically interconnected and assembled in a module, and an array of modules is electrically interconnected together in a single installation to provide a desired amount of electricity. If the light absorbing semiconductor material in each cell, and the electrical components used to transfer the electrical energy produced by the cells, can be suitably protected from the environment, photovoltaic modules can last 25, 30, and even 40 or more years without significant degradation in performance.

As shown in FIG. 1, a photovoltaic module 10 comprises a light-transmitting substrate 12 or front sheet, an encapsulant layer 14, an active photovoltaic cell layer 16, another encapsulant layer 18 and a back-sheet 20. The light-transmitting front sheet substrate, also known as the incident layer, is typically glass or a durable light-transmitting polymer film. The encapsulant layers 14 and 18 adhere the photovoltaic cell layer 16 to the front and back sheets and they seal and protect the photovoltaic cells from moisture and air. The encapsulant layers 14 and 18 are typically comprised of a thermoplastic or thermosetting resin such as ethylene-vinyl acetate copolymer (EVA). The photovoltaic cell layer 16 may be any type of solar cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The back-sheet needs to remain intact and adhered to the rest of the module for the service life of the photovoltaic module, which may extend for multiple decades.

Multilayer laminates have been employed as photovoltaic module back-sheets. One or more of the laminate layers in such back-sheets conventionally comprise a highly durable and long lasting polyvinyl fluoride (PVF) film which is available from E. I. du Pont de Nemours and Company as Tedlar® film. PVF films resist degradation by sunlight and they provide a good moisture barrier properties over long periods of time. PVF films are typically laminated to other polymer films that contribute mechanical and dielectric strength to the back-sheet, such as polyester films, as for example polyethylene terephthalate (PET) films. Other conventional back-sheet laminates are comprised wholly of polyester films, but such back-sheets have been found to experience delamination and degradation over time.

There is a need for a photovoltaic module back-sheet that is durable over extended periods of time, that does not delaminate from the module, and that offers excellent moisture resistance and good electrical insulation properties. There is a further need for such back-sheets that cost less to produce and use.

### SUMMARY

A photovoltaic module comprises an active solar cell layer having a front light receiving side and opposite rear side, an encapsulant layer adhered to the rear side of the active solar cell layer, and a back-sheet adhered to the encapsulant layer. The back-sheet comprises a first polymer film adhered to the encapsulant layer, where the first polymer film comprises 20 to 95 weight percent chlorosulfonated polyolefin based on the weight of the first polymer film, and 1 to 50 weight percent of adhesive based on the weight of the first polymer film.

The adhesive in the first polymer film is selected from thermoplastic polymer adhesives, thermoset polymer adhesives, and rosin based tackifiers. The adhesive of the first polymer film may comprise one or more rosin based tackifiers. Alternatively, the adhesive of said first polymer film may comprise an ethylene copolymer such as ethylene vinyl acetate, ethylene-methyl methacrylate copolymer, ethylene-ethyl methacrylate copolymer, ethylene-propyl methacrylate copolymer, ethylene-butyl methacrylate copolymer, ethylene-methyl acrylate copolymer, ethylene-ethyl acrylate copolymer, ethylene-propyl acrylate copolymer, ethylene-butyl acrylate copolymer, and blends thereof in any ratio. The adhesive may also be an ethylene copolymer formed by the polymerization of ethylene and one or more co-monomers, the co-monomer being selected from a group consisting of methyl methacrylate, methyl acrylic ester, ethyl methacrylate, ethyl acrylic ester, propyl methacrylate, propyl acrylic ester, butyl methacrylate, butyl acrylic ester, methacrylic acid glyceride, methyl hydrogen maleate, ethyl hydrogen maleate, and maleic anhydride.

In one embodiment, the first polymer film comprises 25 to 90 weight percent chlorosulfonated polyethylene, and 5 to 35 weight percent of adhesive selected from thermoplastic and thermoset polymer adhesives and rosin based tackifiers, based on the weight of the first polymer film.

The first polymer film of the back-sheet may further comprise 10 to 70 weight percent of inorganic particulates based on the weight of the first polymer film. The inorganic particulates may be selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof.

In one aspect, the first polymer film comprises a single layer back-sheet having first and second opposite side, where the first side of the first polymer film is adhered directly to the encapsulant layer and wherein the second side of the first polymer film is exposed. This first polymer film has a thickness in the range of 1 to 50 mils, and more preferably in the range of 10 to 40 mils.

According to another aspect, the first polymer film has first and second opposite sides, where the first side of the first polymer film is directly adhered to the encapsulant layer and where the second side of said first polymer film is adhered to a second polymer film. The second polymer film is preferably a polyester film or a fluoropolymer film. A preferred second polymer film is a film consisting essentially of fluoropolymer such as polyvinylfluoride, polyvinylidene fluoride, polytetrafluoroethylene, ethylene-tetrafluoroethylene, poly chloro trifluoroethylene, terpolymer of tetrafluoroethylene, hexafluoropropylene and vinylidene fluoride (THV), and combinations thereof.

According to another aspect, the first polymer film has first and second opposite sides, where the first side of the first polymer film is directly adhered to said encapsulant layer and where the second side of the first polymer film is adhered to a metal layer. A preferred metal layer is from the group of metal foils, sputtered metal layers, and metal oxide layers.

A preferred chlorosulfonated polyolefin is a chlorosulfonated polyethylene having the formula

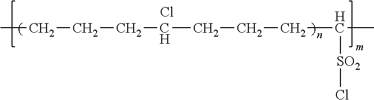

where m and n are positive integers of about 5-25. The chlorosulfonated polyethylene may have a weight average molecular weight of about 75,000 to 300,000.

### BRIEF DESCRIPTION OF THE DRAWING

The detailed description will refer to the following drawing, wherein like numerals refer to like elements:

FIG. 1 is a cross-sectional view of one embodiment of a photovoltaic module.

### DETAILED DESCRIPTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### DEFINITIONS

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet”, “layer” and “film” are used in their broad sense interchangeably. A “back-sheet” is a sheet, layer or film on the side of a photovoltaic module that faces away from a light source, and is generally opaque.

“Encapsulant” layers are used to encase the fragile voltage-generating solar cell layer to protect it from environmental or physical damage and hold it in place in the photovoltaic module. Encapsulant layers may be positioned between the solar cell layer and the incident front sheet layer, between the solar cell layer and the back-sheet backing layer, or both. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to front-sheets, back-sheets, other rigid polymeric sheets and solar cell surfaces, and good long term weatherability.

The term “copolymer” is used herein to refer to polymers containing copolymerized units of two different monomers (a dipolymer), or more than two different monomers.

By “polyolefin” is meant homopolymers and copolymers of C₂-C₈ alpha-monoolefins, including graft copolymers. The copolymers may be dipolymers or higher order copolymers, such as terpolymers or tetrapolymers. Particularly useful examples include homopolymers of C₂-C₃ alpha monoolefins, copolymers of ethylene and carbon monoxide, and copolymers of ethylene and at least one ethylenically unsaturated monomer selected from the group consisting of C₃-C₁₀ alpha monoolefins, C₁-C₁₂ alkyl esters of unsaturated C₃-C₂₀ monocarboxylic acids, unsaturated C₃-C₂₀ mono- or dicarboxylic acids, anhydrides of unsaturated C₄-C₈ dicarboxylic acids, and vinyl esters of saturated C₂-C₁₈ carboxylic acids. Specific examples of these polyolefin polymers include polyethylene, polypropylene, ethylene vinyl acetate copolymers, ethylene acrylic acid copolymers, ethylene methacrylic acid copolymers, ethylene methyl acrylate copolymers, ethylene methyl methacrylate copolymers, ethylene nbutyl methacrylate copolymers, ethylene glycidyl methacrylate copolymers, graft copolymers of ethylene and maleic anhydride, graft copolymers of propylene and maleic anhydride, and copolymers of ethylene with propylene, butene, 3-methyl-1-pentene, hexene, or octene. Preferred polyolefin polymers are polyethylene, ethylene propylene copolymers, ethylene butene copolymers, ethylene octene copolymers, copolymers of ethylene and acrylic acid, copolymers of ethylene and methacrylic acid, and copolymers of ethylene and vinyl acetate. The preferred polyolefin polymers have number average molecular weights within the range of 1,000 to 300,000.

Durable substrates for use in photovoltaic modules are disclosed. Photovoltaic modules made with such durable substrates are also disclosed. The durable substrate is a sheet or film that comprises chlorosulfonated polyolefin polymer. The prefererred chlorosulfonated polyolefin for the photovoltaic module durable substrate is a chlorosulfonated polyethylene (CSPE) polymer. In one aspect, a CSPE polymer containing sheet forms a single layer back-sheet of a photovoltaic module and is adhered to an encapsulent layer that encapsulates the back side of the solar cell of a photovoltaic module. In another aspect, a CSPE polymer containing sheet is adhered to an encapsulant layer on the back side of a solar cell and another layer, such as a polymer film or metal layer, is laminated to a side of the CSPE sheet that is opposite to the solar cell.

In one embodiment, a chlorosulfonated polyolefin containing sheet is provided that is comprised of 25% by weight or more of chlorosulfonated polyolefin, preferably 30% by weight or more of chlorosulfonated polyolefin, and more preferably 40% by weight or more of chlorosulfonated polyolefin. The cholrosulfonated polyolefin is preferably an elastomer or synthetic rubber. The chlorosulfonated polyolefin is a polyolefin that has a chlorine content of about 15-0.60% by weight and preferably about 25-45% by weight, and that has a sulfur content to about 0.1-4% by weight and preferably about 0.7-1.5% by weight. Chlorosulfonated polyolefins are formed by the reaction of polyolefins with chlorine and sulfuryl chloride or sulfur dioxide in solution. Reactive extrusion and solventless processes have also been disclosed, for example in U.S. Pat. No. 3,347,835 and in U.S. Pat. No. 4,554,326. In addition, chlorosulfonation of solvent-swollen ethylene polymers in fluids consisting of fluorocarbons having 1-4 carbon atoms are known.

In a preferred embodiment, a chlorosulfonated polyethylene (CSPE) sheet is incorporated into a photovoltaic module. The CSPE containing sheet is comprised of 25% by weight or more of CSPE, preferably 30% by weight or more of CSPE, and more preferably 40% by weight or more of CSPE. The cholrosulfonated polyethylene has a chlorine content of about 15-60% by weight and preferably about 25-45% by weight, and has a sulfur content to about 0.1-4.0% by weight and preferably about 0.7-1.5% by weight. The CSPE polymer is a partially chlorinated polyethylene containing sulfonyl chloride groups. CSPE is a synthetic rubber or elastomer that is also referred to as CSM and has been sold under the Hypalon® trademark of E. I. du Pont de Nemours and Company.

One useful chlorosulfonated polyethylene has the formula

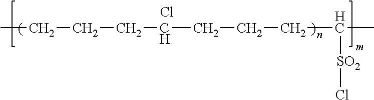

where m and n are positive integers of about 5-25. The polymer has a weight average molecular weight of about 75,000 to 300,000, and preferably about 100,000 to 150,000. Molecular weight, as used herein, is determined by gel permeation chromatography using polymethyl methacrylate as a standard.

Generally, the thickness of the CSPE containing photovoltaic module substrate layer ranges from about 1 to about 50 mils (about 25 microns to about 1.27 mm), and more preferably about 10 to 40 mils (about 0.25 to 1.0 mm). The substrate thickness in embodiments where the CSPE-containing substrate layer functions as a single layer back-sheet that is adhered to a separate encapsulant layer on the back of the solar cell is preferably within the range of about 1 mil (25 microns) to about 30 mils (0.76 mm).

In one preferred embodiment, a CSPE containing photovoltaic module substrate layer is comprised of CSPE combined with one or more tackifiers or polymer adhesives. The CSPE and the tackifiers or polymer adhesives may be mixed by known compounding processes. In one aspect, the CSPE containing sheet comprises comprises 20 to 95% by weight of CSPE as described above, and 1 to 50% by weight of one or more of tackifiers, thermoplastic polymer adhesives and thermoset polymer adhesives, and more preferably and 5 to 30% by weight of one or more of tackifiers, thermoplastic polymer adhesives and thermoset polymer adhesives, and even more preferably and 10 to 30% by weight of one or more of tackifiers, thermoplastic polymer adhesives and thermoset polymer adhesives. The tackifiers and/or thermoplastic polymer adhesives and/or thermoset polymer adhesives serve to improve the adhesion of the CSPE containing sheet to the encapsulant layer of the solar cell of the photovoltaic module.

Tackifiers useful in the disclosed CSPE containing photovoltaic module substrate layer include hydrogenated rosin-based tackifiers, acrylic low molecular weight tackifiers, synthetic rubber tackifiers, hydrogenated polyolefin tackifiers such as polyterpene, and hydrogenated aromatic hydrocarbon tackifiers. Two preferred hydrogenated rosin-based tackifiers include FloraRez 485 glycerol ester hydrogenated rosin tackifier from Florachem Corporation and Stabelite Ester-E hydrogenated rosin-based tackifier from Eastman Chemical.

Thermoplastic polymer adhesives useful in the disclosed CSPE containing photovoltaic module substrate layer include ethylene copolymer adhesives such as ethylene acrylic acid copolymers, ethylene vinyl acetate copolymers, and ethylene methacrylate copolymers. Ethylene copolymer adhesives that may be used as the thermoplastic adhesive may be from the following groups:

ethylene-C₁₋₄ alkyl methacrylate copolymers and ethylene-C₁₋₄ alkyl acrylate copolymers, for example, ethylene-methyl methacrylate copolymers, ethylene-methyl acrylate copolymers, ethylene-ethyl methacrylate copolymers, ethylene-ethyl acrylate copolymers, ethylene-propyl methacrylate copolymers, ethylene-propyl acrylate copolymers, ethylene-butyl methacrylate copolymers, ethylene-butyl acrylate copolymers, and mixtures of two or more copolymers thereof, wherein copolymer units resulting from ethylene account for 50%-99%, preferably 70%-95%, by total weight of each copolymer;

ethylene-methacrylic acid copolymers, ethylene-acrylic acid copolymers, and blends thereof, wherein copolymer units resulting from ethylene account for 50-99%, preferably 70-95%, by total weight of each copolymer;

ethylene-maleic anhydride copolymers, wherein copolymer units resulted from ethylene account for 50-99%, preferably 70-95%, by total weight of the copolymer;

polybasic polymers formed by ethylene with at least two co-monomers selected from C₁₋₄ alkyl methacrylate, C₁₋₄ alkyl acrylate, ethylene-methacrylic acid, ethylene-acrylic acid and ethylene-maleic anhydride, non-restrictive examples of which include, for example, terpolymers of ethylene-methyl acrylate-methacrylic acid (wherein copolymer units resulting from methyl acrylate account for 2-30% by weight and copolymer units resulting from methacrylic acid account for 1-30% by weight), terpolymers of ethylene-butyl acrylate-methacrylic acid (wherein copolymer units resulting from butyl acrylate account for 2-30% by weight and copolymer units resulting from methacrylic acid account for 1-30% by weight), terpolymers of ethylene-propyl methacrylate-acrylic acid (wherein copolymer units, resulting from propyl methacrylate account for 2-30% by weight and copolymer units resulting from acrylic acid account for 1-30% by weight), terpolymers of ethylene-methyl acrylate-acrylic acid (wherein copolymer units resulting from methyl acrylate account for 2-30% by weight and copolymer units resulted from acrylic acid account for 1-30% by weight), terpolymers of ethylene-methyl acrylate-maleic anhydride (wherein copolymer units resulting from methyl acrylate account for 2-30% by weight and copolymer units resulting from maleic anhydride account for 0.2-10% by weight), terpolymers of ethylene-butyl acrylate-maleic anhydride (wherein copolymer units resulting from butyl acrylate account for 2-30% by weight and copolymer units resulted from maleic anhydride account for 0.2-10% by weight), and terpolymers of ethylene-acrylic acid-maleic anhydride (wherein copolymer units resulting from acrylic acid account for 2-30% by weight and copolymer units resulting from maleic anhydride account for 0.2-10% by weight);

copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride, non-restrictive examples of which include, for example, terpolymers of ethylene-butyl acrylate-glycidyl methacrylate, wherein copolymer units resulting from butyl acrylate account for 2-30% by weight and copolymer units resulting from glycidyl methacrylate account for 1-15% by weight;

and blends of two or more above-described materials.

Another ethylene copolymer that may included in the CSPE containing photovoltaic module substrate layer is ethylene vinyl acetate copolymer. Other thermoplastic adhesives that may be utilized in the CSPE containing photovoltaic module substrate layer include polyurethanes, acrylic hot melt adhesives, synthetic rubber, and other synthetic polymer adhseives.

The CSPE containing sheet may further comprise 10% to 70% by weight of inorganic particulates, and more preferably 40% to 65% of inorganic particulates. The inorganic particulates preferably comprise fillers, pigments and other inert additives. Useful filler materials include calcium carbonate, kaolin and clays, alumina trihydrate, talc (magnesium silicate hydroxide), silica, antimony oxide, magnesium hydroxide, barium sulfate, mica, vermiculite, alumina, titania, acicular titanium dioxide, wollastinite and boron nitride. The filler materials may serve to add reinforcement to the sheet or reduce the overall cost of the CSPE containing sheet. Platelet shaped fillers such as mica and talc and/or fibrous fillers may reinforce and strengthen the sheet. Preferred fillers have an average particle size less than 100 microns and preferably less than 10 microns. If the particle size is too large, defects, voids and surface roughness of the sheet may be a problem. If the particle size is too small, the particles may be difficult to disperse and the viscosity may be excessively high. Generally speaking, average particle sizes between 0.5 to 100 microns are preferred. Pigments such as titanium dioxide may be added to the sheet to make the sheet whiter, more opaque and more reflective which may be desirable in a photovoltaic module back-sheet layer.

The chlorosulfonated polyolefin containing photovoltaic module substrate layer may comprise additional additives including, but are not limited to, plasticizers such as polyethylene glycol, processing aides, flow enhancing additives, lubricants, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, adhesives, primers, and reinforcement additives, such as glass fiber and the like. Compounds that help to catalyze cross-linking reactions in CSPE such as inorganic oxides like magnesium oxide may also be used. Such additives typically are added in amounts of less than 3% by weight of the CSPE containing film or sheet layer with the total of such additional additives comprising less than 10% by weight of the CSPE containing layer and more preferably less than 5% by weight of the CSPE containing layer.

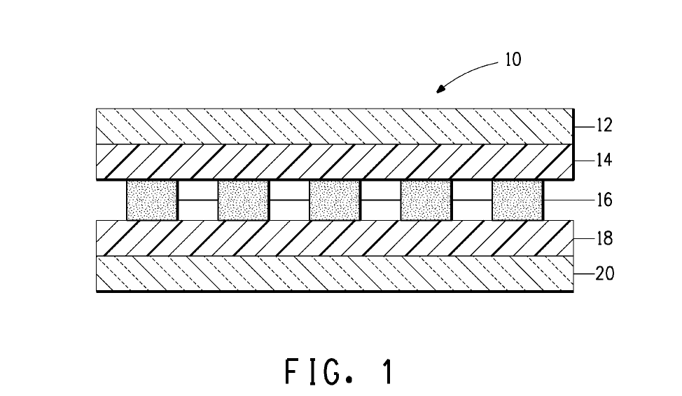

According to one aspect, the chlorosulfonated polyolefin containing film or sheet layer is adhered to an encapsulant layer on the back side of the solar cell. In the photovoltaic module shown in FIG. 1, an encapsulant layer 18 is adhered to the rear side of the active solar cell layer 16. A chlorosulfonated polyolefin containing sheet 20 is adhered to the opposite side of the encapsulant layer 20. The encapsulant layers typically have a thickness greater than or equal to 5 mils, and preferably greater than 10 mils. A preferred encapsulant layer has a thickness in the range of 10 to 30 mils. The encapsulant layers of the photovoltaic module are typically comprised of ethylene methacrylic acid and ethylene acrylic acid, ionomers derived therefrom, or combinations thereof. Such encapsulant layers may also be films or sheets comprising poly(vinyl butyral)(PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and polyethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn lonomer Resins”, Polyelectrolytes, 1976, C, 177-197. Other suitable ionomers are further described in European patent EP1781735. The encapsulant layers may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like. Encapsulant layers may be positioned between the solar cell layer and the incident layer, between the solar cell layer and the backing layer, or both.

In one aspect of the invention, the photovoltaic module with a chlorosulfonated polyolefin containing substrate further comprises one or more other polymeric film layers laminated to the side of the chlorosulfonated polyolefin containing photovoltaic module substrate layer that is opposite the solar cell layer. The other polymer film may be adhered to a CSPE containing sheet 20 that is adhered on its other side to an encapsulant layer 18 like that shown in FIG. 1. The other polymeric film layer(s) may be comprised of polyester, polycarbonate, polypropylene, polyethylene, polypropylene, cyclic. polyloefins; norbornene polymers, polystyrene, syndiotactic polystyrene, styrene-acrylate copolymers, acrylonitrile-styrene copolymers, poly(ethylene naphthalate), polyethersulfone, polysulfone, nylons, poly(urethanes), acrylics, cellulose acetates, cellulose triacetates, cellophane, vinyl chloride polymers, polyvinylidene chloride, vinylidene chloride copolymers, or fluoropolymers such as polyvinyl fluoride, polyvinylidene fluoride, polytetrafluoroethylene, ethylene-tetrafluoroethylene copolymers, poly chloro trifluoroethylene, THV and the like. Preferred other polymeric films include bi-axially oriented poly(ethylene terephthalate) (PET) film and fluoropolymer films, such as polyvinyl fluoride (PVF) film or polyvinylidene fluoride (PVDF) film. Suitable PVF films are more fully disclosed in U.S. Pat. No. 6,632,518. The thickness of such other polymeric film layers is not critical and may be varied depending on the particular application. Generally, the thickness of the other polymeric film layer will range from about 0.1 to about 10 mils (about 0.003 to about 0.26 mm). The other polymeric film layer thickness may be preferably within the range of about 1 mil (0.025 mm) to about 4 mils (0.1 mm). Primers or adhesive bonding layers may be utilized to improve the adhesion between a CSPE containing substrate layer and the other polymeric film layers.

In another embodiment, the photovoltaic module with a CSPE containing substrate further comprises one or more metal layers laminated to the side of the chlorosulfonated polyolefin containing substrate layer that is opposite the solar cell layer. The metal layer(s) can be a thin metal foil such as an aluminum, copper or nickel foil, a plated metal layer, a sputtered metal layer or a metal layer deposited by other mean such as chemical solution deposition. Preferred metal layers include metal foils, metal oxide layers and sputtered metal layers. Such metal layers may be adhered to a chlorosulfonated polyolefin containing sheet 20 that is adhered on its other side to an encapsulant layer 18 like that shown in FIG. 1.

The photovoltaic cell layer (also know as the active layer) of the module is made of an ever increasing variety of materials. Within the present invention, a solar cell is meant to include any article which can convert light into electrical energy. Typical art examples of the various forms of solar cells include, for example, single crystal silicon solar cells, polycrystal silicon solar cells, microcrystalline silicon solar cells, amorphous silicon based solar cells, copper indium (gallium) diselenide solar cells, cadmium telluride solar cells, compound semiconductor solar cells, dye sensitized solar cells, and the like. The most common types of solar cells include multi-crystalline solar cells, thin film solar cells, compound semiconductor solar cells and amorphous silicon solar cells due to relatively low cost manufacturing ease for large scale solar modules.

The photovoltaic module may further comprise one or more front sheet layers or film layers to serve as the light-transmitting substrate (also know as the incident layer). The light-transmitting layer may be comprised of glass or plastic sheets, such as, polycarbonate, acrylics, polyacrylate, cyclic polyolefins, such as ethylene norbornene polymers, metallocene-catalyzed polystyrene, polyamides, polyesters, fluoropolymers and the like and combinations thereof. Glass most commonly serves as the front sheet incident layer of the photovoltaic solar module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass depends on the intended use.

A process of manufacturing the photovoltaic module with chlorosulfonated polyolefin containing substrate will now be disclosed. The photovoltaic module may be produced through a vacuum lamination process. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a photovoltaic cell layer, a back encapsulant layer and a CSPE containing back-sheet layer are laminated together under heat and pressure and a vacuum to remove air. Preferably, the glass sheet has been washed and dried. In an exemplary procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. General art edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the photovoltaic modules as disclosed herein.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The following Examples are intended to be illustrative of the present invention, and are not intended in any way to limit the scope of the present invention described in the claims.

### Test Methods

### Damp Heat Exposure

Damp heat exposure is followed by a peel strength test. The layers of the sample are made with at least one end where the sample layers are not laminated (“free ends”) for use in peel strength testing. The test samples are cut into 1 inch wide strips. Each sample strip has a laminated section at least four inches long and an end with free ends.

The laminated samples are placed into a dark chamber. The sample is preferably mounted at approximately a 45 degree angle to the horizontal. The chamber is then brought to a temperature of 85° C. and relative humidity of 85%. These conditions are maintained for a specified number of hours. Samples are typically removed and tested after an exposure of 1000 hours, because 1000 hours at 85° C. and 85% relative humidity is the required exposure in many photovoltaic module qualification standards.

After 1000 hours in the heat and humidity chamber, the sample strips are removed for peel strength testing. Peel strength is a measure of adhesion of laminated samples. To prepare for the peel strength test, a blade is passed through the laminate samples sequentially to create parallel cuts separated by a known distance (one inch in the experimental results discussed here). The peel strength was measured on an Instron mechanical tester with a 50 kilo loading using a 90° peel test. The free ends of two layers of the laminated sample were put into the clamps of the Instron tester and each layer was pulled in an opposite direction (at an angle of 90° from the sample) at a rate of 12 inches/minute. Usually, a large initial tension force is required to start the peel, and a constant steady-state force is needed to propagate the peel. Testing was stopped after the clamps had moved three inches from each other relative to their starting position. This geometry is based on ASTM D903, a standard test method for peel or stripping strength of adhesive bonds.

### Dielectric Strength

Dielectric strength was measured according to ASTMD1868, a test method used for measuring the dielectric breakdown and dielectric strength of solid electrical insulating material under direct-voltage stress. Dielectric strength was measured on the CSPE containing sample slabs of Table 1 before the slabs were laminated to other layers. Dielectric breakdown voltage measurements were made using a Hipotronic model 800PL power supply. The sample film or substrate being evaluated was placed between two brass electrodes. The humidity around the sample was controlled at 25% relative humidity and the temperature was maintained at 25° C. An increasing voltage was applied to the electrodes starting from a low voltage. The voltage was increased at a steady rate until the breakdown occurred. A breakdown occurs when there is an increase in the current flow followed by arcing. The dielectric strength is the voltage at breakdown (“dielectric breakdown voltage”) divided by the thickness of the sample. The voltage is measured in kilovolts (KV), and the units for the dielectric strength are kilovolt/mil (V/mil).

### Cut Through

Cut through was measured on the CSPE containing sample slabs of Table 1 before the slabs were laminated to other layers. Cut through was measured according to Underwriters Laboratory publication UL 1703 entitled “Flat-Plate Photovoltaic Modules and Panels,” Section 23, as fully described in at column 2, lines 1-53 of U.S. Pat. No. 5,474,620, which is hereby incorporated by reference. Briefly stated, a sample slab was fixed to a flat surface. A test cart with a weighted blade extending at a 45° angle down from the test cart was pull so that the weighted blade was passed over the surface of the test sample at a speed of 150 (±30) mm/s. The blade exerted a force of 8.9 N where the point of the blade contacted the sample surface. The test was repeated in five different directions. Results are visually assessed according to one of the following ratings:

1. No visible marks apparent

2. Slight visible marks apparent

3. Surface indentation apparent

4. Sample cut through apparent

### Preparation of Test Sample Slabs:

The ingredients listed in Table 1 were mixed in a tangential BR Banbury internal mixer made by Farrel Corporation of Ansonia, Conn. The non-polymer additives were charged into the mixing chamber of the Banbury mixer and mixed before the chlorosulfonated polyethylene (CSPE) polymer and any thermoplastic polymer adhesive or rosin tackifier ingredients were introduced into the mixing chamber, in what is know as an upside down mixing procedure. The CSPE and the adhesives or tackifiers used were selected so as to have a softening point or melting point below 95° C.-100° C. in order to achieve good dispersion. The ingredient quantities listed in Table 1 are by weight parts relative to the parts CSPE and other ingredients used in each of the examples.

The speed of the Banbury mixer's rotor was set to 75 rpm and cooling water at tap water temperature was circulated through a cooling jacket around the mixing chamber and through cooling passages in the rotor. The cooling water was circulated to control the heat generated by the mixing. The temperature of the mass being compounded was monitored during mixing. After all of the ingredients were charged into the mixing chamber and the temperature of the mass reached 82° C., a sweep of the mixing chamber was done to make sure that all ingredients were fully mixed into the compounded mass. When the temperature of the compounded mass reached 120° C., it was dumped from the mixing chamber into a metal mold pan.

The compounded mass in the mold pan was then sheeted by feeding the mixture into a 16 inch two roll rubber mill. Mixing of the compound was finished on the rubber mill by cross-cutting and cigar rolling the compounded mass. During sheeting, the mass cooled.

Sample slabs were prepared by re-sheeting the fully compounded mass on a two roll rubber mill in which the rolls were heated to 80° C. The compound was run between the rolls from five to ten times in order to produce a 25 mil thick sheet with smooth surfaces. Six inch by six inch pre-form squares were die cut from the sheet. A number of the pre-forms were put in a compression mold heated to 100° C., and the mold was put into a mechanical press and subjected to pressure. The mold pressure was initially applied and then quickly released and reapplied two times in what is known as bumping the mold, after which the mold pressure was held for 5 minutes. Cooling water was introduced into the press platens in order to reduce the mold temperature. When the mold cooled to 35° C., the press was opened and the sample slabs were removed.

TABLE 1

| | Sample No. | | | | | | |
|---|---|---|---|---|---|---|---|
| | 1 | 2 | 3 | 4 | 5 | 6 | 7 |
| CSPE | 100 | 100 | 100 | 70 | 70 | 70 | 100 |
| Hot Melt Polymer | | 30 | | | | | |
| Adhesive | | | | | | | |
| Hydrogenated Rosin | | | 30 | | | | |
| A Tackifier | | | | | | | |
| Ethylene-Butyl | | | | 30 | | | |
| Acrylate Copolymer | | | | | | | |
| Ethylene Vinyl | | | | | 30 | | |
| Acetate Copolymer | | | | | | | |
| Ethylene-Methyl | | | | | | 30 | |
| Acrylate Copolymer | | | | | | | |
| Hydrogenated Rosin | | | | | | | 30 |
| B Tackifier | | | | | | | |
| Ground Calcium | 85 | 85 | 85 | 85 | 85 | 85 | 85 |
| Carbonate | | | | | | | |
| Titanium Dioxide | 35 | 35 | 35 | 35 | 35 | 35 | 35 |
| Antioxidant | 1 | 1 | 1 | 1 | 1 | 1 | 1 |
| Polyethylene Glycol | 2 | 2 | 2 | 2 | 2 | 2 | 2 |
| Stearamide | 1.5 | 1.5 | 1.5 | 1.5 | 1.5 | 1.5 | 1.5 |
| Magnesium Oxide | 6 | 6 | 6 | 6 | 6 | 6 | 6 |
| UV Stabilizer | 0.8 | 0.8 | 0.8 | 0.8 | 0.8 | 0.8 | 0.8 |
| Total Parts | 231.3 | 261.3 | 261.3 | 231.3 | 231.3 | 261.3 | 261.3 |
| Density (kg/l) | 1.647 | 1.528 | 1.533 | 1.597 | 1.614 | 1.601 | 1.549 |
| Tg (° C.) | −25 | −23 | −14 | −22 | −24 | −23 | −14 |
| Tc (° C.) | 57 | 55 | 47 | 90 | 66 | 83 | 46 |
| Melt Temp (° C.) | 54 | 55 | 54 | 56 | 57 | 56 | 54 |

Ingredient Glossary

| | |
|---|---|
| CSPE | Hypalon ® 45 chlorosulfonated |
| | polyethylene from E. I. du Pont de |
| | Nemours and Company, of Wilmington, |
| | Delaware, USA (“DuPont”) |
| Hot Melt Polymer Adhesive | Euromelt 707 US synthetic hot melt |
| | polymer adhesive from Henkel |
| | Corporation of Dusseldorf, Germany |
| Hydrogenated Rosin A | FloraRez 485 glycerol ester |
| Tackifier | hydrogenated rosin tackifier from |
| | Florachem Corporation |
| Ethylene-Butyl Acrylate | Elvaloy 3517-Si ethylene-butyl acrylate |
| Copolymer | copolymer thermoplastic resin from |
| | DuPont |
| Ethylene Vinyl Acetate | Elvax 360 ethylene-vinyl acetate |
| | copolymer thermoplastic resin from |
| | DuPont |
| Ethylene-Methyl Acrylate | Bynel 22E757 ethylene-methyl acrylate |
| Copolymer | copolymer thermoplastic resin from |
| | DuPont |
| Hydrogenated Rosin B | Stabelite Ester-E hydrogenated rosin- |
| Tackifier | based tackifier from Eastman Chemical |
| | of Kingsport, Tennessee, USA |
| Ground Calcium Carbonate | Atomite ® ground calcium |
| | carbonate/limestone from Imerys of |
| | Roswell, Georgia |
| Titanium Dioxide | TiPure ® R-960 titanium dioxide from |
| | DuPont |
| Antioxidant | Irganox ® 1010 from BASF of |
| | Ludwigshafen, Germany |
| | [Benzenepropanoic acid, 3,5-bis(1,1-dimethyl)-4- |
| | hydroxy-2,2-bis[3-[3,5-bis(1,1-dimethylethyl)-4- |
| | hydroxyphenyl]-1-oxopropoxy]methyl]-1,3- |
| | propanediyl ester] |
| Polyethylene Glycol | Carbowax polyethylene glycol 3350 |
| | plasticizer from Dow Chemical Company |
| | of Midland, Michigan |
| Stearamide | Kemamide ® S stearamide processing |
| | aid from Chemtura Corporation of |
| | Middlebury, Connecticut |
| Magnesium Oxide | Elastomag ® 170 magnesium oxide post |
| | curing agent from Martin Marietta |
| | Magnesia Specialties LLC of Raleigh, |
| | North Carolina |
| UV Stabilizer | Tinuvin 622 LD butanedoic acid, |
| | dimethyl ester, polymer with 4-hydroxy- |
| | 2,2,6,6-tetramethyl-1-piperidineethanol |
| | from from BASF of Ludwigshafen, |
| | Germany |

### Example 1

A laminate sample was made by laminating an ethylene vinyl acetate (EVA) clear sheet between the CSPE sample slab no. 1 described in Table 1 above and a sheet of clear low-iron glass. The glass was ⅛ inch thick, approximately 4 inches long and approximately 4 inch wide. The CSPE test slab was a single layer with a 25 mil thickness and cut to approximately 4 inches long and approximately 4 inch wide. The EVA clear sheet from Bixby International Co., Newburyport, Mass. was 18 mil thick and was cut to 4 inches long and approximately 4 inch wide.

The lamination was accomplished by preparing a layered structure of the glass sheet followed by the sheet of clear EVA, followed by the CSPE test slab no. 1. The layered structure was placed into a lamination press having a platen heated to about 120° C. The layered structure was allowed to rest on the platen for about 6 minutes to preheat the layered structure under vacuum. The lamination press was activated and the layered structure was pressed together using 1 atmosphere of pressure for 14 minutes to permit the EVA to encapsulate the glass and form a sealed sample.

The laminate sample was subjected to the damp heat exposure test described above for 1000 hours and then tested for peel strength. The sample did not undergo significant degradation. During peel strength testing, there was no failure in the bond between the CSPE sample slab and the EVA film. Rather, the EVA film stretched before there was any failure in the bond between the CSPE sample slab and the EVA film.

Another sample of the CSPE slab no. 1 by itself was tested for dielectric breakdown using above described method. The average breakdown voltage was 14 KV.

Another sample of the CSPE slab no. 1 by itself was tested according to the cut through test described above. Slight marks were left on the surface of the sample.

### Example 2

A laminate sample was made by the same process as in Example 1 under the same process conditions, except that the CSPE sample slab no. 1 described in Table 1 was replaced with the CSPE/hot melt adhesive sample slab no. 2 described in Table 1 above.

The laminate sample was subjected to the damp heat exposure test described above for 1000 hours and then tested for peel strength. The sample did not undergo significant degradation. During peel strength testing, there was no failure in the bond between the CSPE/hot melt adhesive sample slab and the EVA film. Rather, the EVA film stretched before there was any failure in the bond between the CSPE/hot melt adhesive sample slab and the EVA film.

Another sample of the CSPE/hot melt adhesive slab no. 2 by itself was tested for dielectric breakdown using above described method. The average breakdown voltage was 14 KV.

Another sample of the CSPE/hot melt adhesive slab no. 2 by itself was tested according to the cut through test described above. No marks were left on the surface of the sample.

### Example 3

A laminate sample was made by the same process as in Example 1 under the same process conditions, except that the CSPE sample slab no. 1 described in Table 1 was replaced with the CSPE/glycerol ester hydrogenated rosin tackifier sample slab no. 3 described in Table 1 above.

The laminate sample made in such manner was subjected to the damp heat exposure test as described herein above for 1000 hours and then tested for peel strength. During peel strength testing, there was no failure in the bond between the CSPE/rosin tackifier sample slab and the EVA film. Rather, the EVA film stretched before there was any failure in the bond between the CSPE/rosin tackifier sample slab and the EVA film.

Another sample of the CSPE/rosin tackifier slab no. 3 by itself was tested for dielectric breakdown using above described method. The average breakdown voltage was 15.1 KV.

Another sample of the CSPE/rosin tackifier slab no. 3 by itself was tested according to the cut through test described above. No marks were left on the surface of the sample.

### Example 4

A laminate sample was made by the same process as in Example 1 under the same process conditions, except that the CSPE sample slab no. 1 described in Table 1 was replaced with the CSPE/ethylene-butyl acrylate copolymer sample slab no. 4 described in Table 1 above.

The laminate sample was subjected to the damp heat exposure test described above for 1000 hours and then tested for peel strength. During peel strength testing, there was no failure in the bond between the CSPE/ethylene-butyl acrylate copolymer sample slab and the EVA film. Rather, the EVA film stretched before there was any failure in the bond between the CSPE/ethylene-butyl acrylate copolymer sample slab and the EVA film.

Another sample of the CSPE/ethylene-butyl acrylate copolymer sample slab no. 4 by itself was tested for dielectric breakdown using above described method. The average breakdown voltage was 18.6 KV.

Another sample of the CSPE/ethylene-butyl acrylate copolymer sample slab no. 4 by itself was tested according to the cut through test described above. Very slight marks were left on the surface of the sample.

### Example 5

A laminate sample was made by the same process as in Example 1 under the same process conditions, except that the CSPE sample slab no. 1 described in Table 1 was replaced with the CSPE/ethylene vinyl acetate copolymer sample slab no. 5 described in Table 1 above.

The laminate sample made in such manner was subjected to the damp heat exposute test described above for 1000 hours and then tested for peel strength. During peel, strength testing, there was no failure in the bond between the CSPE/EVA sample slab and the EVA film. Rather, the EVA film stretched before there was any failure in the bond between the CSPE/EVA sample slab and the EVA film.

Another sample of the CSPE/EVA sample slab no. 5 by itself was tested for dielectric breakdown using above described method. The average breakdown voltage was 17.8 KV.

Another sample of the CSPE/EVA sample slab no. 5 by itself was tested according to the cut through test described above. Very slight marks were left on the surface of the sample.

### Example 6

A laminate sample was made by the same process as in Example 1 under the same process conditions, except that the CSPE sample slab no. 1 described in Table 1 was replaced with the CSPE/ethylene-methyl acrylate copolymer sample slab no. 6 described in Table 1 above.

The laminate sample made in such manner was subjected to the damp heat exposure test described above for 1000 hours and then tested for peel strength. During peel strength testing, there was no failure in the bond between the CSPE/ethylene-methyl acrylate sample slab and the EVA film. Rather, the EVA film stretched before there was any failure in the bond between the CSPE/ethylene-methyl acrylate sample slab and the EVA film.

Another sample of the CSPE/ethylene-methyl acrylate sample slab no. 6 by itself was tested for dielectric breakdown using above described method. The average breakdown voltage was 17.4 KV.

Another sample of the CSPE/ethylene-methyl acrylate sample slab no. 6 by itself was tested according to the cut through test described above. Slight marks were left on the surface of the sample.

### Example 7

A laminate sample was made by the same process as in Example 1 under the same process conditions, except that the CSPE sample slab no. 1 described in Table 1 was replaced with the CSPE/Ester-E hydrogenated rosin-based tackifier sample slab no. 7 described in Table 1 above.

The laminate sample made in such manner was subjected to the damp heat exposure test as described herein above for 1000 hours and then tested for peel strength. During peel strength testing, there was no failure in the bond between the CSPE/rosin tackifier sample slab and the EVA film. Rather, the EVA film stretched before there was any failure in the bond between the CSPE/rosin tackifier sample slab and the EVA film.

Another sample of the CSPE/Ester-E hydrogenated rosin-based tackifier sample slab no. 7 by itself was tested for dielectric breakdown using above described method. The average breakdown voltage was 17.4 KV.

Another sample of the CSPE/Ester-E hydrogenated rosin-based tackifier sample slab no. 7 by itself was tested according to the cut through test described above. Slight marks were left on the surface of the sample.

What is claimed is:

1. A photovoltaic module comprising:
an active solar cell layer having a front light receiving side and opposite rear side;
an encapsulant layer adhered to the rear side of the active solar cell layer; and
a back-sheet adhered to said encapsulant layer, said back-sheet comprising a first polymer film adhered to said encapsulant layer, said first polymer film comprising 20 to 95 weight percent chlorosulfonated polyolefin based on the weight of the first polymer film, and 1 to 50 weight percent of adhesive based on the weight of the first polymer film, said adhesive being selected from thermoplastic polymer adhesives, thermoset polymer adhesives and tackifiers.

2. The photovoltaic module of claim 1 wherein said back-sheet further comprises 10 to 70 weight percent of inorganic particulates.

3. The photovoltaic module of claim 2 wherein said inorganic particulates are selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof.

4. The photovoltaic module of claim 1 wherein said first polymer film comprises 25 to 90 weight percent chlorosulfonated polyethylene, and 5 to 35 weight percent of adhesive selected from thermoplastic polymer adhesives, thermoset polymer adhesives and rosin based tackifiers.

5. The photovoltaic module of claim 1 wherein said first polymer film comprises a single layer back-sheet having first and second opposite side, wherein the first side of said polymer film is adhered directly to said encapsulant layer and wherein the second side of said first polymer film is exposed.

6. The photovoltaic module of claim 5 wherein said first polymer film has a thickness in the range of 10 to 50 mils.

7. The photovoltaic module of claim 1 wherein said first polymer film has first and second opposite sides, wherein the first side of the first polymer film is directly adhered to said encapsulant layer and wherein said second side of said first polymer film is adhered to a second polymer film.

8. The photovoltaic module of claim 7 wherein said second polymer film is a polyester film or a fluoropolymer film.

9. The photovoltaic module of claim 8 wherein said second polymer film is a film consisting essentially of fluoropolymer selected from polyvinylfluoride, polyvinylidene fluoride, polytetrafluoroethylene, ethylene-tetrafluoroethylene and combinations thereof.

10. The photovoltaic module of claim 1 wherein said first polymer film has first and second opposite sides, wherein the first side of the polymer film is directly adhered to said encapsulant layer and wherein said second side of said first polymer film is adhered to a metal layer.

11. The photovoltaic module of claim 10 wherein said metal layer is from the group of metal foils, sputtered metal layers, and metal oxide layers.

12. The photovoltaic module of claim 1 wherein the chlorosulfonated polyolefin is a chlorosulfonated polyethylene having the formula 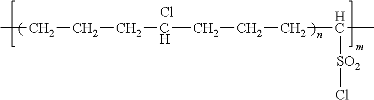
where m and n are positive integers of about 5-25.

13. The photovoltaic module of claim 12 wherein the chlorosulfonated polyethylene has a weight average molecular weight of about 75,000 to 300,000.

14. The photovoltaic module of claim 1 wherein the adhesive of said first polymer film comprises one or more rosin based tackifiers.

15. The photovoltaic module of claim 1 wherein the adhesive of said first polymer film comprises an ethylene copolymer.

16. The photovoltaic module of claim 15 wherein the ethylene copolymer comprises ethylene vinyl acetate.

17. The photovoltaic module of claim 15 wherein the ethylene copolymer is from the group consisting of ethylene-methyl methacrylate copolymer, ethylene-ethyl methacrylate copolymer, ethylene-propyl methacrylate copolymer, ethylene-butyl methacrylate copolymer, ethylene-methyl acrylate copolymer, ethylene-ethyl acrylate copolymer, ethylene-propyl acrylate copolymer, ethylene-butyl acrylate copolymer, and blends thereof in any ratio.

18. The photovoltaic module of claim 15 wherein the ethylene copolymer is formed by the polymerization of ethylene and one or more co-monomers, the co-monomer being selected from a group consisting of methyl methacrylate, methyl acrylic ester, ethyl methacrylate, ethyl acrylic ester, propyl methacrylate, propyl acrylic ester, butyl methacrylate, butyl acrylic ester, methacrylic acid glyceride, methyl hydrogen maleate, ethyl hydrogen maleate, and maleic anhydride.

19. The photovoltaic module of claim 1 wherein the chlorosulfonated polyolefin is an elastomer or a synthetic rubber.
